(19) United States
(12) Patent Application Publication
(10) Pub. No.: US 2017/0170804 A1
(43) Pub. Date: Jun. 15, 2017

(54) PIEZOELECTRIC RESONATOR FOR ULTRASONIC TRANSDUCER AND MANUFACTURING METHOD THEREOF

(71) Applicant: NIHON DEMPA KOGYO CO., LTD., Tokyo (JP)

(72) Inventor: Akihiro NOHARA, Saitama (JP)

(73) Assignee: NIHON DEMPA KOGYO CO., LTD., Tokyo (JP)

(21) Appl. No.: 15/368,674

(22) Filed: Dec. 5, 2016

(30) Foreign Application Priority Data
Dec. 9, 2015 (JP) 2015-240172

(51) Int. Cl. H03H 9/13; H03H 3/02; B06B 1/06; H03H 9/17

(52) U.S. Cl. CPC H03H 9/132; H03H 9/176; H03H 3/02; B06B 1/0644

(57) ABSTRACT

A piezoelectric resonator for an ultrasonic transducer includes a piezoelectric vibrating body, a signal electrode, a ground electrode, multiple bottomed groove portions, and a ground common electrode. The piezoelectric vibrating body is constituted of a piezoelectric ceramics. Multiple bottomed groove portions are formed to expose the principal surface of the piezoelectric vibrating body in a slice direction along a scanning direction of the piezoelectric resonator on the signal electrode. The ground common electrode is formed on at least one end portion of an end surface of the piezoelectric vibrating body in the slice direction and adjacent to both end portions in the scanning direction. The groove portions separate the signal electrode into a plurality of the signal electrodes in the scanning direction, and the ground common electrode electrically connects electrodes at both ends out of the signal electrodes which are separated to the ground electrode.

### CROSS-REFERENCE TO RELATED APPLICATIONS

This application is based on and claims priority under 35 U.S.C. §119 to Japanese Patent Application No. 2015-240172, filed on Dec. 9, 2015, the entire content of which is incorporated herein by reference.

Technical Field

This disclosure relates to an ultrasonic transducer that transmits and receives ultrasonic sound waves from a piezoelectric resonator, which is an ultrasound transmitting/receiving portion, to a subject (living body) and that retrieves two-dimensional data for an ultrasonic diagnosis of the subject by scanning the piezoelectric resonator in a linear direction. This disclosure particularly relates to a piezoelectric resonator manufactured without cutting the piezoelectric resonator into every one ch (channel) during manufacturing the piezoelectric resonator for an ultrasonic transducer and a manufacturing method thereof.

Description of the Related Art

In a conventional ultrasonic transducer, an ultrasonic transducer main body 100 is constituted of members such as a second acoustic matching layer 110, a first acoustic matching layer 111, a piezoelectric resonator 114, a backing material 118, a front circuit board (a flexible printed circuit board) 120 as illustrated in FIG. 5A. These members are cut with a dicing saw after lamination, and are constituted to be divided into respective channels by grooves 114a (see Japanese Unexamined Patent Application Publication No. 2013-191940).

Therefore, in the conventional ultrasonic transducer, as illustrated in FIG. 5B, a signal electrode is formed on one principal surface of the piezoelectric resonator 114 and a ground electrode is formed on the other principal surface, and after the flexible printed circuit board 120 is connected to the signal electrode, the piezoelectric resonator 114 is cut into every one channel with the dicing saw or similar tool to have a structure that is divided by the grooves 114a. Then, in order to electrically connect each of the divided electrodes on an ultrasonic radiant surface side to cause each of the electrodes to function as a common ground, a common electrode 114b is soldered over the respective electrodes to electrically connect of the respective electrodes (see Japanese Patent No. 3384889).

There is a conventional ultrasonic transducer that forms a plurality of electrodes by forming bottomed grooves on one surface of a piezoelectric body included in an ultrasonic probe. These grooves are arranged in a slice direction, which is perpendicular to a scanning direction of the ultrasonic probe, and in a continuous manner in the scanning direction. A weighting of a center part of a piezoelectric body is simply increased in transmission and reception of ultrasonic sound waves. Thus, uniforming a beam width in the slice direction of the piezoelectric body and ensuring obtaining the ultrasonic sound waves with a low side lobe (see Japanese Unexamined Patent Application Publication No. 2005-296127).

However, in the conventional ultrasonic transducer, as described above, after connecting a flexible printed circuit board to each of the electrodes, a piezoelectric resonator is divided by being cut into every one channel with a dicing saw or similar tool, and in order to cause the electrodes on an ultrasonic radiant surface side to be a common ground, it is required to solder over the whole electrodes, which are once divided, to electrically connect the electrodes.

Therefore, cutting equipment such as a dicing saw is necessary to cut the piezoelectric resonator. In addition, a soldering operation is indispensable to electrically connect the respective piezoelectric vibrating bodies, which have been cut. Consequently, an expensive facility device such as the dicing saw is necessary and an extra man-hour for such as soldering is required in a manufacturing process of the piezoelectric resonator, thereby increasing a cost for manufacturing the piezoelectric resonator.

A need thus exists for a piezoelectric resonator for an ultrasonic transducer and a manufacturing method thereof which are not susceptible to the drawback mentioned above.

### SUMMARY

According to an aspect of this disclosure, there is provided a piezoelectric resonator for an ultrasonic transducer includes a piezoelectric vibrating body, a signal electrode, a ground electrode, a plurality of bottomed groove portions, and a ground common electrode. The piezoelectric vibrating body is constituted of a piezoelectric ceramics. The signal electrode is formed on one principal surface of the piezoelectric vibrating body. The ground electrode is formed on another principal surface of the piezoelectric vibrating body. The plurality of bottomed groove portions is formed to expose the principal surface of the piezoelectric vibrating body in a slice direction along a scanning direction of the piezoelectric resonator on the signal electrode. The ground common electrode is formed on at least one end portion of an end surface of the piezoelectric vibrating body in the slice direction and adjacent to both end portions in the scanning direction. The bottomed groove portions separate the signal electrode into a plurality of the signal electrodes in the scanning direction, and the ground common electrode electrically connects electrodes at both ends out of the signal electrodes which are separated to the ground electrode.

### BRIEF DESCRIPTION OF THE DRAWINGS

The foregoing and additional features and characteristics of this disclosure will become more apparent from the following detailed description considered with reference to the accompanying drawings, wherein:

FIG. 1A illustrates a ground electrode forming surface of a piezoelectric resonator according to this disclosure, and its plan view, its front view along a scanning direction, and its side view along a slice direction;

FIG. 1B illustrates a signal electrode forming surface of the piezoelectric resonator in an inverted state according to this disclosure, and its plan view, its front view along the scanning direction, and its side view along the slice direction;

FIG. 2A and FIG. 2B illustrate plan views, front views, and side views where a flexible printed circuit board is connected to the signal electrode of the piezoelectric resonator according to this disclosure illustrated in FIG. 1A and FIG. 1B;

FIG. 3 is a perspective view of the piezoelectric resonator viewed from a side of the ground electrode forming surface of the piezoelectric resonator according to this disclosure;

FIG. 4 is a flowchart illustrating respective processes of a manufacturing method of the piezoelectric resonator according to this disclosure;

FIG. 5A illustrates a perspective view of a transducer main body of a conventional ultrasonic transducer; and

FIG. 5B illustrates a perspective view of the piezoelectric resonator where the flexible printed circuit board is connected to its signal electrodes.

### DETAILED DESCRIPTION

The following description describes embodiments of a piezoelectric resonator according to this disclosure used for an ultrasonic transducer main body of an ultrasonic transducer and a manufacturing method thereof, based on the accompanying drawings.

Configuration of Piezoelectric Resonator According to this Disclosure

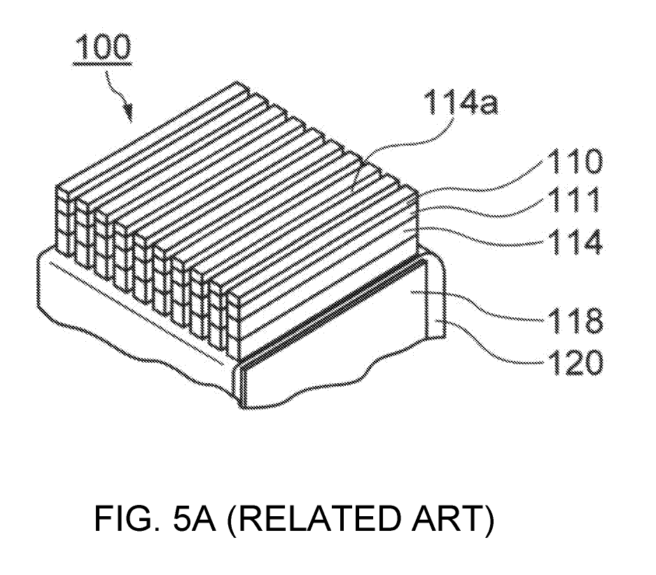

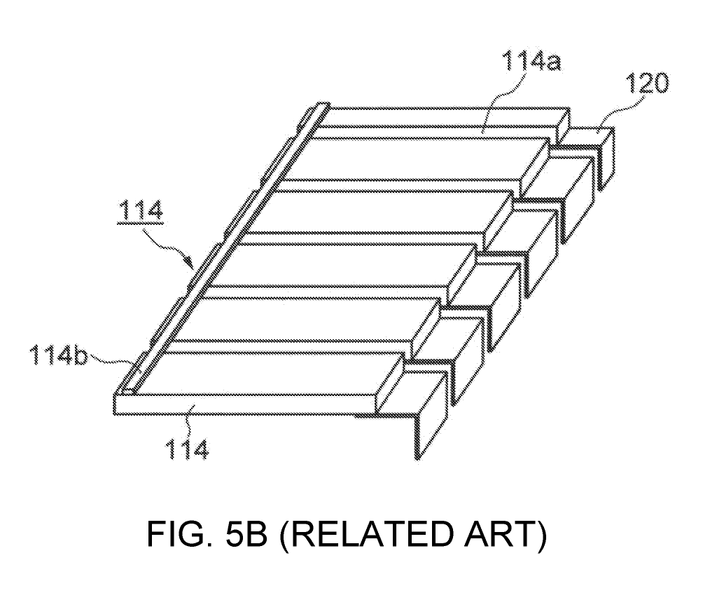

An ultrasonic transducer equipped with a piezoelectric resonator according to this disclosure is, similarly to a conventional ultrasonic transducer, constituted of members such as a laminated second acoustic matching layer, a first acoustic matching layer, a piezoelectric resonator, a flexible printed circuit board, which is electrically connected to a backing material and a signal electrode of the piezoelectric resonator, and a copper foil, which is electrically connected to a ground electrode, as illustrated in FIG. 5A described above.

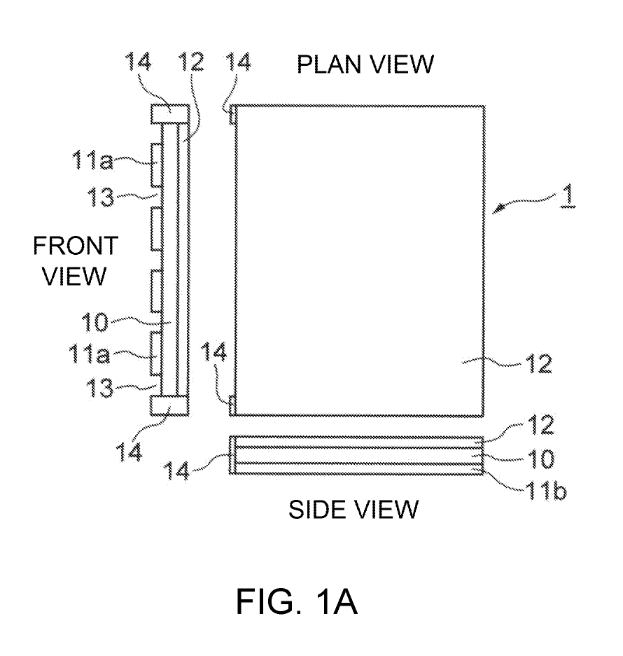

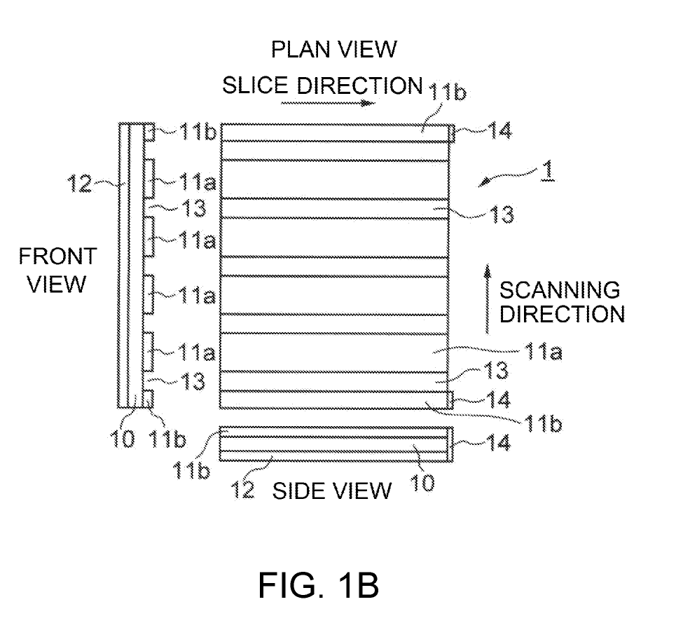

As illustrated in FIG. 1A and FIG. 1B, a piezoelectric resonator 1 according to this disclosure, which is included in an ultrasonic transducer, is constituted of a piezoelectric ceramics, for example, a lead zirconate titanate (PZT). One principal surface of the piezoelectric resonator 1 is formed with signal electrodes 11a, and the other principal surface is formed with a ground electrode 12, by electroless plating Ni (nickel) and Au (gold).

Here, FIG. 1A illustrates a ground electrode forming surface of the piezoelectric resonator according to this disclosure, and its plan view, its front view along a scanning direction, and its side view along a slice direction. The front view and the side view illustrate exposed end surface portions of a PZT resonator body 10 in the scanning direction and the slice direction.

FIG. 1B illustrates a signal electrode forming surface of the piezoelectric resonator according to this disclosure being in an inverted state, and its plan view, its front view along the scanning direction, and its side view along the slice direction. These drawings illustrate the exposed end surface portions of the PZT resonator body (piezoelectric vibrating body) 10 in the scanning direction and the slice direction.

As illustrated in FIG. 1B, on the signal electrode forming surface of the PZT resonator body 10, signal electrodes 11a are formed by electroless plating Ni (nickel) and Au (gold), which will be described later. Then, the plurality of signal electrodes 11a are formed by forming a plurality of bottomed grooves 13 by removing a part of the surface of the signal electrode 11a, which is formed by the electroless plating, to expose a part of the principal surface of the PZT resonator body 10 using a photolithography technique that uses, for example, etching with masking the surfaces where the signal electrodes 11a are formed, such that the number of elements in the slice direction becomes, for example, 64 to 256 channels (ch) of independent signal electrodes 11a.

With these plurality of the bottomed grooves 13, the PZT resonator body 10 and the signal electrode 11a are not separated but integrated.

In addition to this, a ground common electrode 14 is formed by electroless plating Ni (nickel) and Au (gold) on at least one end portion of an end surface of the PZT resonator body 10 in the slice direction and adjacent to both end portions in the scanning direction, as illustrated in the front view in FIG. 1A.

Respective elements of the signal electrodes 11a on both ends in the signal electrodes 11a separated by the bottomed grooves 13 are electrically connected to a ground electrode 11b with this ground common electrode 14 to share the ground electrode.

Here, in this embodiment, the ground common electrodes 14 are formed only on both end portions of the ultrasonic radiant surface side of the PZT resonator body 10 by electroless plating. Therefore, the end surface of the PZT resonator body 10 in the scanning direction is exposed and seen as illustrated in the front view in FIG. 1A.

While in the above-described embodiment, the ground common electrode 14 is formed only on both end portions of the ultrasonic radiant surface side of the PZT resonator body 10 by electroless plating to reduce the manufacturing cost of the PZT resonator body 10, the ground common electrode 14 may be formed on whole end surface of the ultrasonic radiant surface side of the PZT resonator body 10 by performing an additional plating operation.

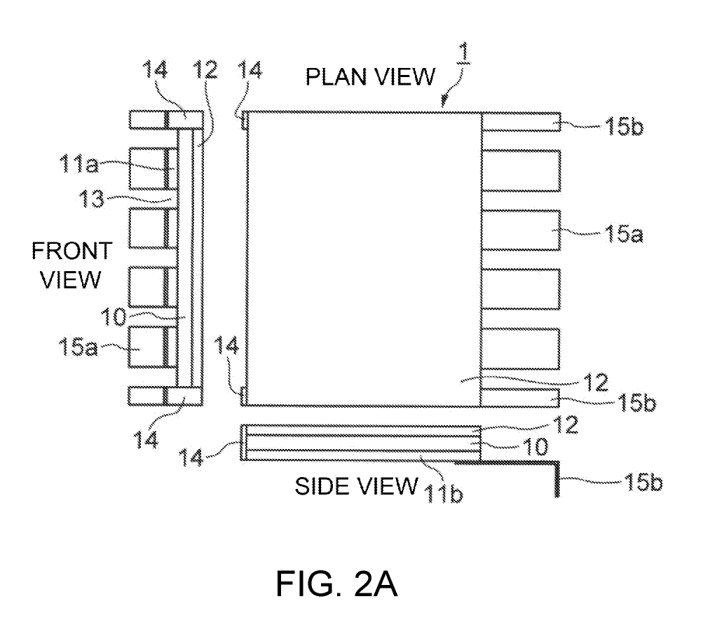

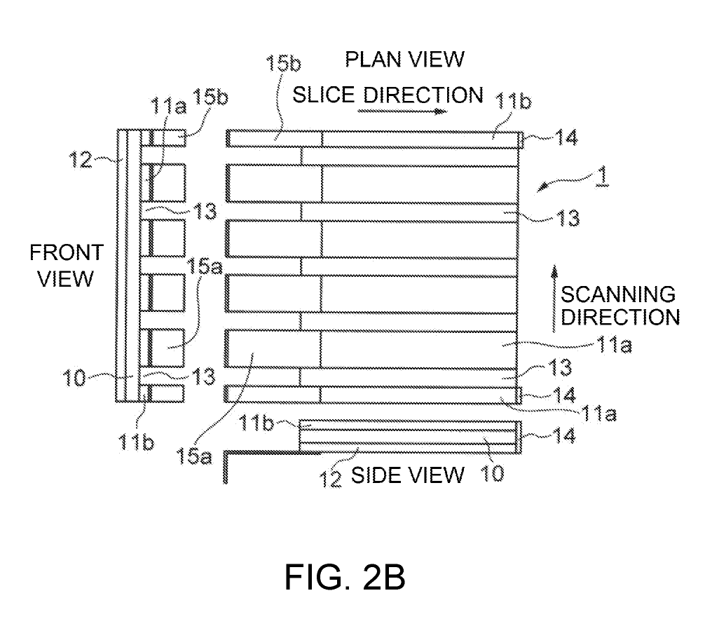

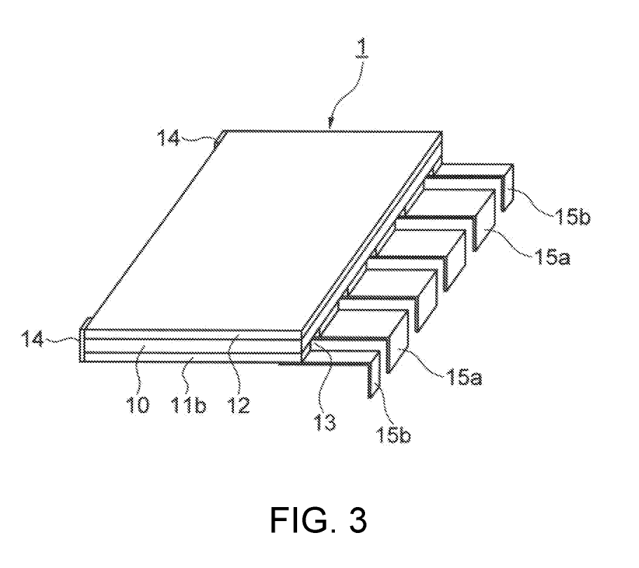

Furthermore, each of the signal electrodes 11a that is patternized in every one channel (ch) of the PZT resonator body 10 formed as described above is electrically connected to a flexible printed circuit board 15, which is formed with a conductor pattern for every one channel (ch) and leads the ultrasonic signal from the signal electrode 11a, as illustrated in FIG. 2A, FIG. 2B, and FIG. 3. The ground common electrodes 14 formed on both end portions of the end surface of the ultrasonic radiant surface side of the PZT resonator body 10 are electrically connected to the flexible printed circuit board 15 to share the round electrode. The ultrasonic ground is led from the ground common electrode 14, and the ground electrode 12 of the piezoelectric vibrating body 10 is connected to the ground pattern of the flexible printed circuit board 15.

Since the piezoelectric resonator according to this disclosure includes the ground common electrode 14, the flexible printed circuit board 15 is separated into the signal electrode 11a side and the ground electrode 11b side.

This ensures electrically connecting the signal electrode 11a and the ground electrode 11b simultaneously to flexible printed circuit boards 15a and 15b, and this eliminates the need for the connecting operation of the ground common electrode, as illustrated in FIG. 5A and FIG. 5B, which has been necessary in the conventional examples.

Manufacturing Method of Piezoelectric Resonator According to this Disclosure

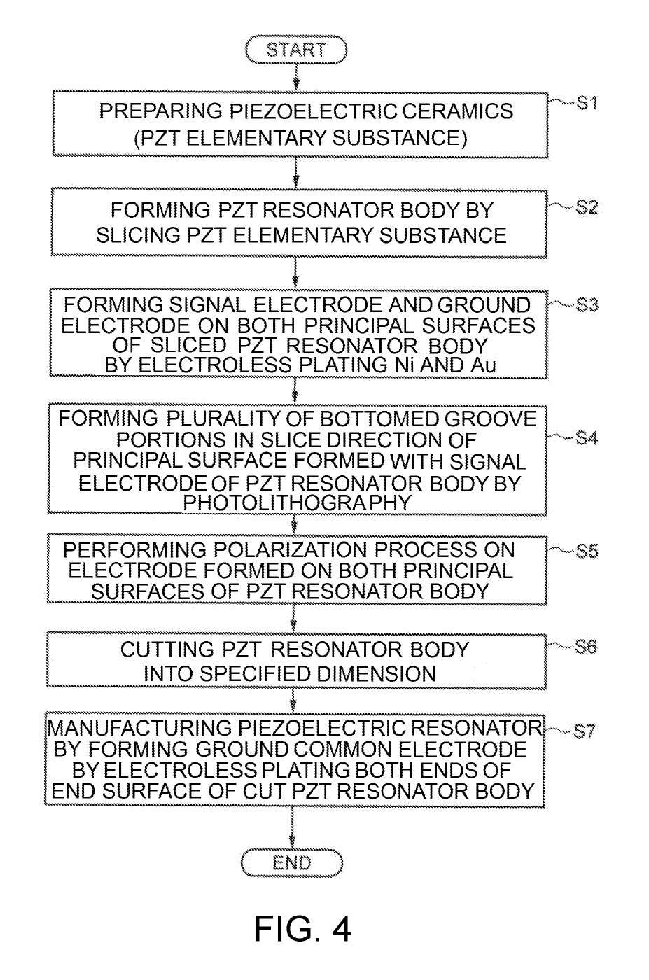

Next, the manufacturing method of the piezoelectric resonator according to this disclosure will be described based on a flowchart illustrated in FIG. 4.

First, a piezoelectric ceramics, for example, PZT (lead zirconate titanate) elementary substance is prepared at Step S1.

Next, the PZT resonator body is formed by slicing the PZT elementary substance (for example, length×width is 95 mm×95 mm) with the dicing saw or similar tool at Step S2.

At Step S3, the signal electrode is formed by electroless plating Ni (nickel) and Au (gold) on the whole principal surface of one side of the sliced PZT resonator body. Similarly, the ground electrode is formed by electroless plating Ni (nickel) and Au (gold) on the whole principal surface of the other side.

Furthermore, at Step S4, the bottomed groove portions (for example, the channel (ch) number of 64 to 256) are formed on one principal surface of the PZT resonator body formed with the signal electrodes in the slice direction perpendicular to the scanning direction of the ultrasonic transducer using a photolithography technique such as etching, and the signal electrode that is patternized for every one channel (ch) is formed in a state where every one channel (ch) is separated and independent.

At Step S5, a polarization process is performed by applying an electric field to the electrode formed on both principal surfaces of the PZT resonator body to reduce a deterioration of the piezoelectric effect due to later cutting and dicing of the PZT resonator body subjected to the polarization process.

Then, at Step S6, the PZT resonator body is cut into a specified dimension (such as length×width is 44×7 mm).

Finally, at Step S7, the ground common electrode is formed on the end surface of the PZT resonator body on the ultrasonic radiant surface side by electroless plating Ni (nickel) and Au (gold) (thickness of approximately 1 μm) on both end portions of the end surface in the scanning direction or over the whole end surface of the ultrasonic transducer to straddle across the respective signal electrodes separated by the plurality of groove portions, thereby manufacturing the piezoelectric resonator.

The signal electrode of the piezoelectric resonator thus manufactured is electrically connected to the flexible printed circuit board, which leads a signal from the signal electrode. The ground common electrode, which is formed on at least one end portion of an end surface of the PZT resonator body in the slice direction and adjacent to both end portions in the scanning direction, is electrically connected to the flexible printed circuit board, which leads the ultrasonic ground from the ground electrode.

In the piezoelectric resonator for the ultrasonic transducer of this disclosure, the piezoelectric vibrating body may be constituted of a PZT resonator body.

Furthermore, in the piezoelectric resonator for the ultrasonic transducer of this disclosure, the ground common electrode may be formed on both end portions of the end surface of the piezoelectric vibrating body.

Furthermore, in the piezoelectric resonator for the ultrasonic transducer of this disclosure, an ultrasonic signal may be led from the piezoelectric vibrating body by electrically connecting a flexible printed circuit board to each of the signal electrodes which are separated.

In the piezoelectric resonator for the ultrasonic transducer of this disclosure, an ultrasonic ground may be led from the piezoelectric vibrating body by electrically connecting a flexible printed circuit board to electrodes on both ends out of the signal electrodes separated with the ground common electrode.

A manufacturing method of a piezoelectric resonator for an ultrasonic transducer of this disclosure includes preparing a piezoelectric ceramics (PZT) elementary substance, forming a piezoelectric vibrating body by slicing the piezoelectric ceramics elementary substance, forming signal electrodes on one principal surface of the piezoelectric vibrating body which is sliced and ground electrodes on another principal surface by electroless plating Ni and Au, forming a plurality of bottomed groove portions in a slice direction of the principal surface formed with the signal electrodes of the piezoelectric vibrating body along a scanning direction by a photolithography technique, performing a polarization process to the electrodes formed on both principal surfaces of the piezoelectric vibrating body and cutting the piezoelectric vibrating body subjected to the polarization process into a specified dimension. The signal electrodes which are separated are electrically connected by forming a ground common electrode using electroless plating on an end surface of an ultrasonic radiant surface side of the piezoelectric vibrating body which is cut.

A piezoelectric resonator for an ultrasonic transducer can be manufactured easily and at low-price without cutting the piezoelectric resonator into every one channel.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. A piezoelectric resonator for an ultrasonic transducer, the piezoelectric resonator comprising:
a piezoelectric vibrating body constituted of a piezoelectric ceramics;
a signal electrode formed on one principal surface of the piezoelectric vibrating body; and
a ground electrode formed on another principal surface of the piezoelectric vibrating body, wherein:
a plurality of bottomed groove portions is formed to expose the principal surface of the piezoelectric vibrating body in a slice direction along a scanning direction of the piezoelectric resonator on the signal electrode,
a ground common electrode is formed on at least one end portion of an end surface of the piezoelectric vibrating body in the slice direction and adjacent to both end portions in the scanning direction, and
the bottomed groove portions separate the signal electrode into a plurality of the signal electrodes in the scanning direction, and the ground common electrode electrically connects electrodes at both ends out of the signal electrodes which are separated to the ground electrode.

2. The piezoelectric resonator according to claim 1, wherein
the piezoelectric vibrating body is constituted of a PZT resonator body.

3. The piezoelectric resonator according to claim 1, wherein
the ground common electrode is formed on both end portions of the end surface of the piezoelectric vibrating body in the scanning direction.

4. The piezoelectric resonator according to claim 1, wherein
an ultrasonic signal is led from the piezoelectric vibrating body by electrically connecting a flexible printed circuit board to each of the signal electrodes which are separated.

5. The piezoelectric resonator according to claim 1, wherein
an ultrasonic ground is led from the piezoelectric vibrating body by electrically connecting a flexible printed circuit board to electrodes on both ends out of the signal electrodes separated with the ground common electrode.

6. A manufacturing method of a piezoelectric resonator for an ultrasonic transducer according to claim 1, the manufacturing method comprising:
preparing a piezoelectric ceramics elementary substance;
forming a piezoelectric vibrating body by slicing the piezoelectric ceramics elementary substance;
forming signal electrodes on one principal surface of the piezoelectric vibrating body which is sliced and ground electrodes on another principal surface by electroless plating Ni and Au;
forming a plurality of bottomed groove portions in a slice direction of the principal surface formed with the signal electrodes of the piezoelectric vibrating body along a scanning direction by a photolithography technique;
performing a polarization process to electrodes formed on both principal surfaces of the piezoelectric vibrating body; and
cutting the piezoelectric vibrating body subjected to the polarization process into a specified dimension, wherein
the signal electrodes which are separated are electrically connected by forming a ground common electrode using plating on an end surface of an ultrasonic radiant surface side of the piezoelectric vibrating body which is cut.
